(19) United States
(12) Patent Application Publication
(10) Pub. No.: US 2026/0044646 A1
(43) Pub. Date: Feb. 12, 2026

(54) GENERATION OF PREMORBID BONE MODELS FOR PLANNING ORTHOPEDIC SURGERIES

(71) Applicant: Howmedica Osteonics Corp., Mahwah, NJ (US)

(72) Inventor: Emile Ducrocq, Brest (FR)

(21) Appl. No.: 19/099,372

(22) PCT Filed: Jul. 31, 2023
(86) PCT No.: PCT/US2023/029121

§ 371 Date: Jan. 28, 2025

Related U.S. Application Data
(60) Provisional application No. 63/370,155, filed on Aug. 2, 2022.

(51) Int. Cl. G06F 30/27; G06N 3/0455; G06N 3/0475; G06T 7/00

(52) U.S. Cl. CPC G06F 30/27; G06N 3/0455; G06N 3/0475; G06T 7/0012; G06T 2207/30008

(57) ABSTRACT

A method comprising: for each respective training iteration of a plurality of training iterations: applying a generator machine learning (ML) model of a generative adversarial network (GAM) to input data to generate an output bone model for tire respective training iteration: applying a second ML model of the GAN to the output bone model to generate a discriminator output for the respective training iteration, wherein the discriminator output for the respective training iteration comprises a level of confidence that the first ML model generated the output bone model: determining a loss value for the respective training iteration based on the discriminator output tor the respective training iteration; and updating parameters of the first ML model or the second ML model based on the loss value for the respective training iteration.

This application claims priority to U.S. Provisional Patent Application 63/370,155, filed Aug. 2, 2022, the entire content of which is incorporated by reference.

### BACKGROUND

Orthopedic surgeries are often very complex, and consequently may require detailed planning. For example, when performing a total shoulder arthroplasty, a surgeon may need to carefully select appropriate orthopedic prostheses and plan how the selected orthopedic prostheses are to be positioned. When planning an orthopedic surgery, a typical goal is to restore the ability of a patient to move at a joint in the same manner as the patient did prior to the onset of a pathology affecting the joint.

### SUMMARY

This disclosure describes example techniques for generating premorbid bone models. The premorbid bone models may be used for planning orthopedic surgeries. For instance, a premorbid bone model may assist a surgeon to understand how the patient moved at a joint prior to onset of a pathology affecting the joint. As described herein, a planning system may apply a premorbid reconstruction machine learning (ML) model (e.g., a first ML model) to a morbid bone model of a bone of a patient to generate a premorbid bone model of the bone of the patient. The premorbid reconstruction ML model may be trained using a generative adversarial network (GAN). For example, a training system may perform a plurality of training iterations. During a training iteration, the premorbid reconstruction ML model may generate, based on input data for the training iteration, an output bone model for the training iteration. A discriminator ML model (e.g., a second ML model) of the GAN may generate, based on the output bone model for the training iteration, a discriminator output for the training iteration. The discriminator output for the training iteration may comprise a level of confidence that the premorbid reconstruction ML model generated the output bone model for the training iteration. The training system may determine a loss value for the training iteration based on the discriminator output for the respective training iteration. The training system may update parameters of the premorbid reconstruction ML model or the discriminator ML model based on the loss value for the respective training iteration.

In one example, this disclosure describes a method comprising: for each respective training iteration of a plurality of training iterations: applying a first machine learning (ML) model of a generative adversarial network (GAN) to input data for the respective training iteration to generate an output bone model for the respective training iteration; applying a second ML model of the GAN to the output bone model for the respective training iteration to generate a discriminator output for the respective training iteration, wherein the discriminator output for the respective training iteration comprises a level of confidence that the first ML model generated the output bone model for the respective training iteration; determining a loss value for the respective training iteration based on the discriminator output for the respective training iteration; and updating parameters of the first ML model or the second ML model based on the loss value for the respective training iteration.

In another example, this disclosure describes a method for generating a premorbid bone model of a bone of a patient, the method comprising: obtaining a morbid bone model of the bone of the patient; and applying a machine learning (ML) model to the morbid bone model to generate the premorbid bone model of the bone of the patient, wherein the ML model has been trained in a generative adversarial network (GAN) to generate premorbid bone models.

In another example, this disclosure describes a computing system comprising: a storage system configured to store a generator machine learning (ML) model of a generative adversarial network (GAN) and a second ML model of the GAN; and processing circuitry configured to: apply the first ML model to input data for the respective training iteration to generate an output bone model for the respective training iteration; apply the second ML model to the output bone model for the respective training iteration to generate a discriminator output for the respective training iteration, wherein the discriminator output for the respective training iteration comprises a level of confidence that the first ML model generated the output bone model for the respective training iteration; determine loss value for the respective training iteration based on the discriminator output for the respective training iteration; and update parameters of the first ML model or the second ML model based on the loss value for the respective training iteration.

In another example, this disclosure describes a computing system comprising: a storage system configured to store a morbid bone model of a bone of a patient; and processing circuitry configured to apply a generator machine learning (ML) model to the morbid bone model to generate a premorbid bone model of the bone of the patient, wherein the ML model has been trained in a generative adversarial network (GAN) to generate premorbid bone models.

The details of various examples of the disclosure are set forth in the accompanying drawings and the description below. Various features, objects, and advantages will be apparent from the description, drawings, and claims.

### BRIEF DESCRIPTION OF DRAWINGS

FIG. 1 is a block diagram illustrating an example system that may be used to implement the techniques of this disclosure.

FIG. 2 is a block diagram illustrating example components of a premorbid reconstruction machine learning model, in accordance with one or more techniques of this disclosure.

FIG. 3 is a block diagram illustrating example components of a training system, in accordance with one or more techniques of this disclosure.

FIG. 4 is a block diagram illustrating example components of a planning system, in accordance with one or more techniques of this disclosure.

FIG. 5A is a conceptual diagram illustrating an example morbid bone model.

FIG. 5B is a conceptual diagram illustrating an example premorbid bone model.

FIG. 6 is a flowchart illustrating an example operation of the training system, in accordance with one or more techniques of this disclosure.

FIG. 7 is a flowchart illustrating an example operation performed by a generative adversarial network (GAN) training system during a training iteration, in accordance with one or more techniques of this disclosure.

FIG. 8 is a flowchart illustrating an example operation for generating a premorbid bone model in accordance with one or more techniques of this disclosure.

FIG. 9 is a conceptual diagram illustrating an example point cloud learning model in accordance with one or more techniques of this disclosure.

FIG. 10 is a block diagram illustrating an example architecture of a T-Net model in accordance with one or more techniques of this disclosure.

FIG. 11, which is described in greater detail elsewhere in this disclosure, illustrates another example 3D convolutional selective autoencoder configured to generate 3-dimensional images representing premorbid bone models according to techniques of this disclosure.

### DETAILED DESCRIPTION

Knowledge of the premorbid shape of a bone of a joint of a patient may be helpful in determining how to select and position orthopedic prostheses so that the patient has a range of motion comparable to a range of motion that the patient had prior to the onset of a pathology affecting the bone. For example, it may be helpful to understand that original shape of a glenoid fossa of a scapula prior to erosion or trauma to a rim of the glenoid fossa. Thus, it may be helpful to obtain a premorbid bone model of a bone when planning an orthopedic surgery. A premorbid bone model may comprise one or more 2D images of a premorbid bone, a 3D image of a premorbid bone, a 3D point cloud representing a premorbid bone, or another type of representation of a premorbid bone. In the context of this disclosure, the term “premorbid bone” may refer to an earlier state of the bone, such as prior to an onset of a primary pathology that is to be addressed in an orthopedic surgery. For instance, a premorbid bone may be a bone prior to the onset of osteoarthritis, trauma, and or other pathology.

Obtaining a premorbid bone model may be challenging for a variety of reasons. For instance, morbid bones (e.g., bones affected by a pathology) may be defined in a wide variety of ways. In other words, the shapes of morbid bones of individual patients may be relatively unique and, as a result, it may be difficult for a machine learning (ML) model to learn how to map morbid bone models to appropriate premorbid bone models. Moreover, because patients seldomly undergo medical imaging (e.g., computed tomography (CT) scans, magnetic resonance imaging (MRI) scans, etc.) of a bone prior to the onset of a pathology affecting the bone, it is difficult to obtain training datasets that accurately reflect “before” and “after” versions of the bone. Thus, when using conventional techniques, it may be difficult to obtain sufficient training data to train a ML model to generate an appropriate premorbid bone model from a given morbid bone model.

This disclosure describes techniques that may enable a ML model to generate premorbid bone models based on morbid bone models. For example, a training system may perform a plurality of training iterations. During a training iteration, a premorbid reconstruction ML model (e.g., a first ML model) of a generative adversarial network (GAN) may generate, based on input data for the training iteration, an output bone model for the training iteration. The input data may include randomized data. The training premorbid bone models may include bone models of premorbid bones of patients collected, e.g., from patient datasets 118. A discriminator ML model (e.g., a second ML model) of the GAN may generate, based on the output bone model for the training iteration, a discriminator output for the training iteration. The discriminator output for the training iteration may comprise a level of confidence that the premorbid reconstruction ML model generated the output bone model for the training iteration (e.g., as opposed to the output bone model for the respective training iteration representing a real premorbid bone). The training system may determine a loss value for the training iteration based on the discriminator output for the respective training iteration. The training system may update parameters of the premorbid reconstruction ML model or the discriminator ML model based on the loss value for the respective training iteration.

In this way, the training system trains the discriminator ML model to improve its ability to discriminate between output bone models generated by the premorbid reconstruction ML model and output bone models not generated by the premorbid reconstruction ML model. The training system also trains the premorbid reconstruction ML model to improve its ability to generate more convincing output premorbid bone models. After training of the premorbid reconstruction ML model is complete, the premorbid reconstruction ML model may be used without use of the discriminator ML model. In this way, an ML model (e.g., the premorbid reconstruction ML model) may be trained to generate premorbid bone models without needing to rely on large numbers of morbid bone models and corresponding premorbid bone models.

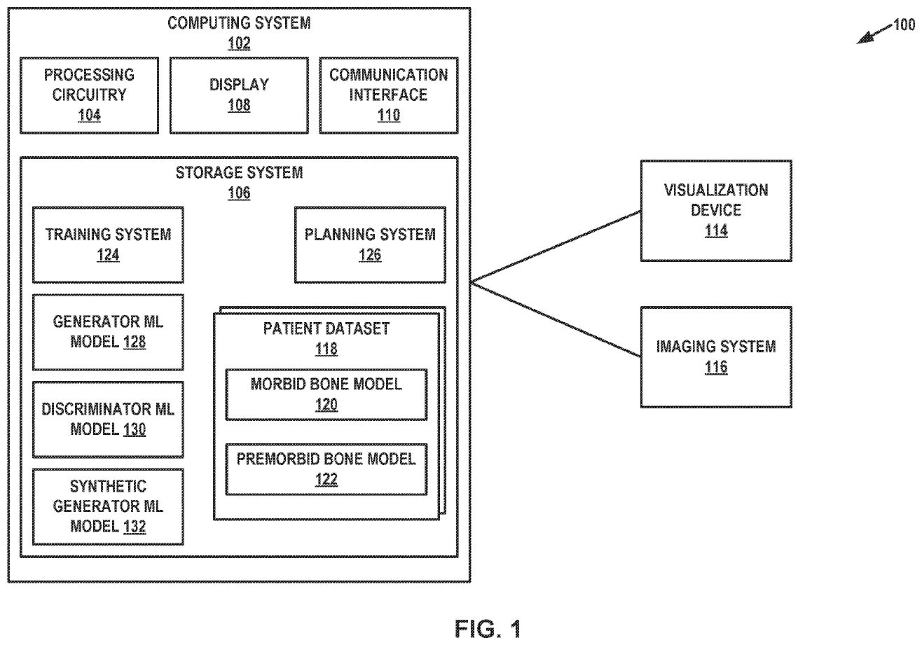

FIG. 1 is a block diagram illustrating an example system 100 that may be used to implement the techniques of this disclosure. In the example of FIG. 1, system 100 includes a computing system 102. Computing system 102 is an example of one or more computing devices that are configured to perform one or more example techniques described in this disclosure. Computing system 102 may include various types of computing devices, such as server computers, personal computers, smartphones, laptop computers, and other types of computing devices. In some examples, computing system 102 includes multiple computing devices that communicate with each other. In other examples, computing system 102 includes only a single computing device. Computing system 102 includes processing circuitry 104, a storage system 106, a display 108, and a communication interface 110. Display 108 may be optional, such as in examples where computing system 102 is a server computer.

Examples of processing circuitry 104 include one or more microprocessors, digital signal processors (DSPs), application specific integrated circuits (ASICs), field programmable gate arrays (FPGAs), discrete logic, software, hardware, firmware or any combinations thereof. Processing circuitry 104 may be implemented as fixed-function circuits, programmable circuits, or a combination thereof. Fixed-function circuits refer to circuits that provide particular functionality and are preset on the operations that can be performed. Programmable circuits refer to circuits that can be programmed to perform various tasks and provide flexible functionality in the operations that can be performed. For instance, programmable circuits may execute software or firmware that cause the programmable circuits to operate in the manner defined by instructions of the software or firmware. Fixed-function circuits may execute software instructions (e.g., to receive parameters or output parameters), but the types of operations that the fixed-function circuits perform are generally immutable. In some examples, the one or more of the units may be distinct circuit blocks (fixed-function or programmable), and in some examples, the one or more units may be integrated circuits. In some examples, processing circuitry 104 is dispersed among a plurality of computing devices in computing system 102. In some examples, processing circuitry 104 is contained within a single computing device of computing system 102. Processing circuitry 104 may include arithmetic logic units (ALUs), elementary function units (EFUs), digital circuits, analog circuits, and/or programmable cores, formed from programmable circuits. In examples where the operations of processing circuitry 104 are performed using software executed by the programmable circuits, storage system 106 may store the object code of the software that processing circuitry 104 receives and executes, or another memory within processing circuitry 104 (not shown) may store such instructions. Examples of the software include software designed for surgical planning.

Storage system 106 may be formed by any of a variety of memory devices, such as dynamic random access memory (DRAM), including synchronous DRAM (SDRAM), magnetoresistive RAM (MRAM), resistive RAM (RRAM), or other types of memory devices. Examples of display 108 include a liquid crystal display (LCD), a plasma display, an organic light emitting diode (OLED) display, or another type of display device. In some examples, storage system 106 may include multiple separate memory devices, such as multiple disk drives, memory modules, etc., that may be dispersed among multiple computing devices or contained within the same computing device.

Communication interface 110 may include hardware circuitry that enables computing system 102 to communicate (e.g., wirelessly or using wires) to other computing systems and devices, such as a visualization device 114 and an imaging system 116. In some examples, communication interface 110 may communicate with other computing systems and devices via a network, which may include various types of communication networks including one or more wide-area networks, such as the Internet, local area networks, and so on. In some examples, the network may include wired and/or wireless communication links.

Visualization device 114 may utilize various visualization techniques to display image content to a surgeon. In some examples, visualization device 114 is a computer monitor or display screen. In some examples, visualization device 114 may be a mixed reality (MR) visualization device, virtual reality (VR) visualization device, holographic projector, or other device for presenting extended reality (XR) visualizations. For instance, in some examples, visualization device 114 may be a Microsoft HOLOLENST™ headset, available from Microsoft Corporation, of Redmond, Washington, USA, or a similar device, such as, for example, a similar MR visualization device that includes waveguides. The HOLOLENS™ device can be used to present 3D virtual objects via holographic lenses, or waveguides, while permitting a user to view actual objects in a real-world scene, i.e., in a real-world environment, through the holographic lenses. In some examples, there may be multiple visualization devices for multiple users.

Visualization device 114 may utilize visualization tools that are available to utilize patient image data to generate three-dimensional models of bones, segmentation masks, or other data to facilitate preoperative planning. These tools may allow surgeons to design and/or select surgical guides and implant components that closely match the patient's anatomy. These tools can improve surgical outcomes by customizing a surgical plan for each patient. An example of such a visualization tool is the BLUEPRINT™ system available from Stryker Corp. The surgeon can use the BLUEPRINT™ system to select, design or modify appropriate implant components, determine how best to position and orient the implant components and how to shape the surface of the bone to receive the components, and design, select or modify surgical guide tool(s) or instruments to carry out the surgical plan. The information generated by the BLUEPRINT™ system may be compiled in a preoperative surgical plan for the patient that is stored in a database at an appropriate location, such as storage system 106, where the preoperative surgical plan can be accessed by the surgeon or other care provider, including before and during the actual surgery.

Imaging system 116 may comprise one or more devices configured to generate medical image data. For example, imaging system 116 may include a device for generating CT images. In some examples, imaging system 116 may include a device for generating MRI images. Furthermore, in some examples, imaging system 116 may include one or more computing devices configured to process data from imaging devices in order to generate medical image data. For example, the medical image data may include a 3D image of one or more bones of a patient. In this example, imaging system 116 may include one or more computing devices configured to generate the 3D image based on CT images or MRI images. In some examples, the medical image data may include a point cloud representing one or more bones of a patient. In this example, imaging system 116 may include one or more computing devices configured to generate the point cloud. Each point in the point cloud may correspond to a set of 3D coordinates of a point on a surface of a bone of the patient. Imaging system 116 may generate the point cloud by identifying the surfaces of the one or more bones in images and sampling points on the identified surfaces. In other examples, computing system 102 may include one or more computing devices configured to generate the medical image data based on data from devices in imaging system 116.

Storage system 106 of computing system 102 may store instructions that, when executed by processing circuitry 104, cause computing system 102 to perform various activities. For instance, in the example of FIG. 1, storage system 106 may store instructions that, when executed by processing circuitry 104, cause computing system 102 to perform activities associated with a planning system 126. For ease of explanation, rather than discussing computing system 102 performing activities when processing circuitry 104 executes instructions, this disclosure may simply refer to planning system 126 or components thereof as performing the activities, or may directly describe computing system 102 as performing the activities.

In the example of FIG. 1, storage system 106 includes one or more patient datasets 118. Each of patient datasets 118 may include data associated with a patient. The data associated with a patient may include demographic information of the patient, a diagnosis of the patient, a surgical plan for the patient, and other types of information of the patient. Additionally, the data associated with a patient may include bone models for the patient. The bone models for a patient may include a morbid bone model 120 for the patient and a premorbid bone model 122 for the patient. Morbid bone model 120 may be a bone model representing a current (morbid) state of a bone of the patient. Premorbid bone model 122 may be a bone model represent a previous (premorbid) state of the bone of the patient. For instance, premorbid bone model 122 may represent a state of the bone prior to an onset of a pathology affecting the bone. Computing system 102 may obtain morbid bone model 120 based on medical imaging data generated by imaging system 116. In this disclosure, the term “bone” may refer to a whole bone or a bone fragment. In some examples, storage system 106 does not include patient datasets 118.

Morbid bone model 120 may be generated in one of a variety of ways. For example, computing system 102 or imaging system 116 may generate morbid bone model 120 based on CT data, MRI data, or data from another medical imaging technology. In some examples, morbid bone model 120 may be generated based on data from a handheld probe that a surgeon uses to pick out points on a bone.

Furthermore, storage system 106 may include instructions that are executable by processing circuitry 104. In the example of FIG. 1, storage system 106 includes instructions associated with a training system 124 and a planning system 126. Storage system 106 may also store a premorbid reconstruction ML model 128 and a discriminator ML model 130. In other examples, computing system 102 may include instructions associated with planning system 126 and premorbid reconstruction ML model 128 and not training system 124 or discriminator ML model 130. For instance, after training of premorbid reconstruction ML model 128 is complete, a copy of premorbid reconstruction ML model 128 may be provided to a computing system that includes instructions associated with planning system 126 and not training system 124. Processing circuitry 104 may execute the instructions associated with training system 124 and planning system 126. Execution of instructions by processing circuitry 104 may cause computing system 102 to perform various actions. For ease of explanation, this disclosure may describe training system 124 and planning system 126 (or components thereof) as performing actions when processing circuitry 104 executes instructions associated with training system 124 and planning system 126.

During training, premorbid reconstruction ML model 128 and discriminator ML model 130 may form part of a GAN. Training system 124 may be configured to perform a plurality of training iterations to train premorbid reconstruction ML model 128 and discriminator ML model 130. For example, training system 124 may alternate between performing one or more training epochs to train premorbid reconstruction ML model 128 and one or more training epochs to train discriminator ML model 130. Training system 124 may perform the plurality of training iterations during such a training epoch. During a training iteration, premorbid reconstruction ML model 128 may generate, based on input data for the training iteration, an output bone model for the training iteration. Premorbid reconstruction ML model 128 may be an autoencoder. In some examples, premorbid reconstruction ML model 128 may have a U-Net architecture. Premorbid reconstruction ML model 128 may reconstruct premorbid bone models from a wide variety of input bone models, including morbid bone models and premorbid bone models. Premorbid reconstruction ML model 128 and the GAN may belong to one of a variety of different types, such as contractive autoencoder, variational autoencoder, vanilla GAN, conditional GAN, deep convolutional GAN, and so on. In some examples, premorbid reconstruction ML model 128 may be previously trained to reconstruct premorbid bone models based on training premorbid bone models.

Discriminator ML model 130 may generate, based on discriminator input (e.g., the output bone model for the training iteration, a real premorbid bone model), a discriminator output for the training iteration. In some examples, the discriminator output for the training iteration may comprise a level of confidence that premorbid reconstruction ML model 128 generated the output bone model for the training iteration. Training system 124 may determine a loss value for the training iteration based on the discriminator output for the respective training iteration. Training system 124 may update parameters of premorbid reconstruction ML model 128 or discriminator ML model 130 based on the loss value for the respective training iteration. For instance, if training system 124 may update parameters of premorbid reconstruction ML model 128 if the training iteration is part of an epoch to train premorbid reconstruction ML model 128 or may update parameters of discriminator ML model 130 if the training iteration is part of an epoch to train discriminator ML model 130.

In some examples, the discriminator output generated by discriminator ML model 130 may classify of the discriminator input as being one of a plurality of classes. A first class corresponds to the discriminator input being a premorbid bone model generated by premorbid reconstruction model 128. A second class corresponds to the discriminator input being a premorbid bone model not generated by premorbid construction model 128. A third class corresponds to the discriminator input being a morbid bone model. In such examples, GAN training unit 304 may perform a supervised learning process on discriminator ML model 130 in which GAN training unit 304 provides training examples that include premorbid bone models and morbid bone models to discriminator ML model 130. Additionally training discriminator ML model 130 in this way may prevent drift in the discriminator output generated by discriminator ML model 130 that may occur if discriminator ML model 130 were only trained on discriminator inputs of supposedly premorbid bone models.

Planning system 126 may be configured to assist a surgeon with planning an orthopedic surgery. After training system 124 has trained premorbid reconstruction ML model 128, planning system 126 may apply premorbid reconstruction ML model 128 to a morbid bone model (e.g., morbid bone model 120) of a bone of a patient to generate a premorbid bone model (e.g., premorbid bone model 122) of the bone of the patient. Planning system 126 may use the premorbid bone model to help a surgeon plan a surgery. In some examples, planning system 126 may cause display 108 or visualization device 114 to output the premorbid bone model for display. In some examples, planning system 126 may use the premorbid bone model to perform auto-planning. For example, planning system 126 may recommend implantation of a specific type of an orthopedic prosthesis based on the premorbid bone model. In some examples, planning system 126 may recommend a surgery type (e.g., anatomic total shoulder arthroplasty or reverse total shoulder arthroplasty) based on the premorbid bone model. Planning system 126 may apply business rules, one or more ML models, or other types of processes to perform planning for a surgery.

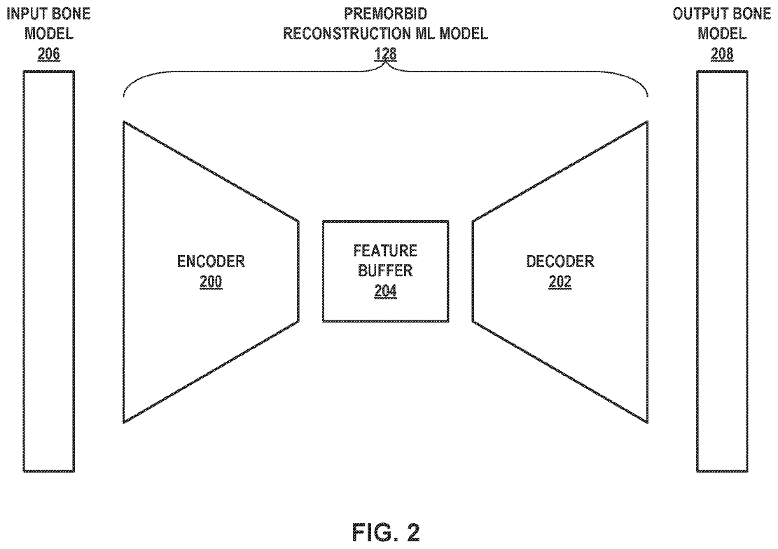

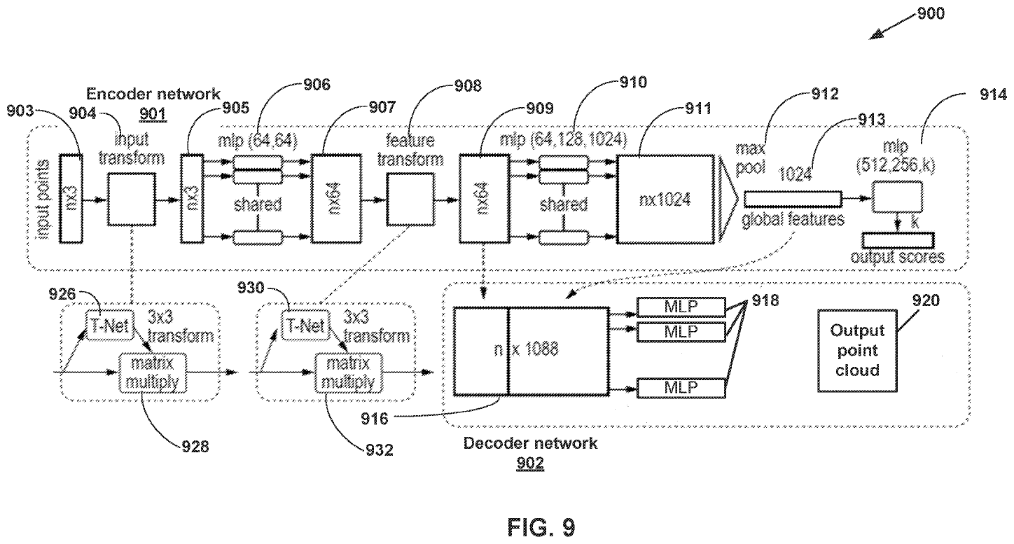

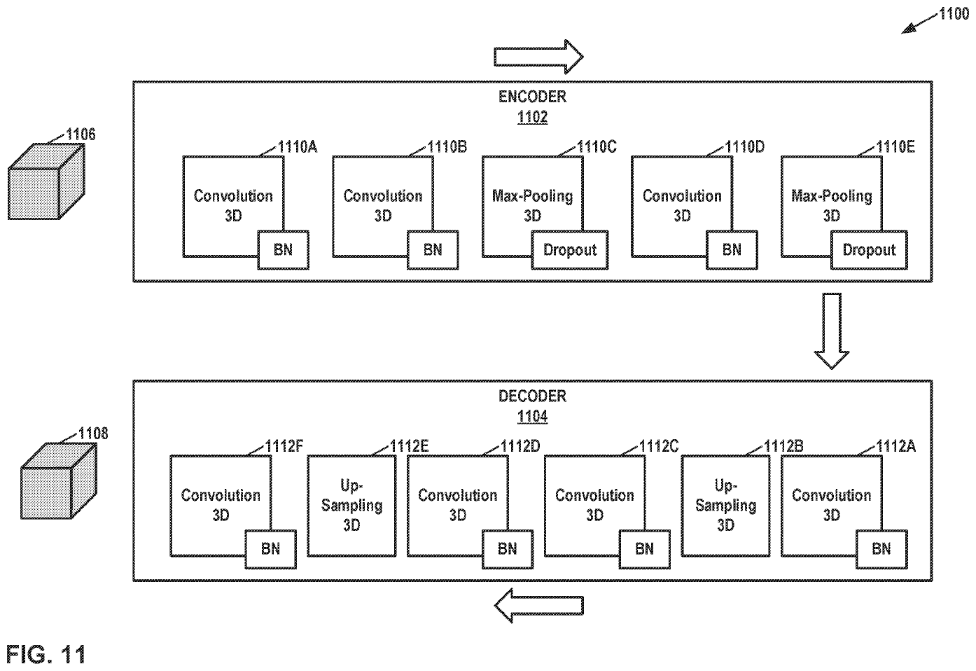

In some examples, computing system 102 may include a synthetic premorbid reconstruction ML model 132 (e.g., a third ML model) configured to generate synthetic morbid bone models. In some examples, training system 124 trains synthetic premorbid reconstruction ML model 132 based on existing morbid bone models. In some examples, training system 124 trains synthetic premorbid reconstruction ML model 132 based on non-morbid (healthy) bone models. Training system 124 may use the synthetic morbid bone models for further training of premorbid reconstruction ML model 128. In other words, training system 124 may train the premorbid reconstruction ML model 128 (e.g., a first ML model) based on the synthetic premorbid bone models. Thus, generating the synthetic morbid bone models may be a form of data augmentation that increases the number and diversity of training data than what otherwise may be available for training premorbid reconstruction ML model 128. Increasing the diversity of training data may improve the robustness of premorbid reconstruction ML model 128 with respect to lighting, contrast, noise, and/or other factors. The additional premorbid reconstruction ML model may have the same or similar structure and may be trained in the same way as any of the examples provided in this disclosure with respect to premorbid reconstruction ML model 128. For instance, synthetic premorbid reconstruction ML model 132 may have an architecture such as that shown in FIG. 2, FIG. 9, FIG. 11, or as described elsewhere in this disclosure. In some examples, synthetic premorbid reconstruction ML model 132 may be trained using a GAN in a similar way as premorbid reconstruction ML model 128.

FIG. 2 is a block diagram illustrating example components of premorbid reconstruction ML model 128, in accordance with one or more techniques of this disclosure. As shown in the example of FIG. 2, generative ML model 128 may include an encoder 200, a decoder 202, and a feature buffer 204. Encoder 200 comprises a convolutional neural network (CNN). Decoder 202 comprises a CNN that contains transposed convolutional layers. Transposed convolutional layers are also called deconvolutional layers. Feature buffer 204 stores the output of encoder 200. Input to decoder 202 includes data stored in feature buffer 204. Feature buffer 204 may include fewer features than either input bone model 206 or output bone model 208. For instance, in some examples, feature buffer 204 may be a buffer of 16 features. A feature may be a number.

Encoder 200 may include a series of layers. The layers of encoder 200 may include an input layer, one or more hidden layers, and an output layer. The hidden layers of encoder 200 may include one or more convolutional layers. Neurons in a convolutional layer are not connected to each value in an input matrix of the convolutional layer. Rather, neurons in a convolutional layer are connected to values in a receptive field with the input matrix of the convolutional layer. A neuron in a convolutional layer (i.e., a convolutional layer neuron) performs a convolution, such as a dot product, to generate an output value based on values generated by neurons in the receptive field of the convolutional layer neuron and weights of connections between the convolutional layer neuron and the neurons in the receptive field of the convolutional layer neuron. The hidden layers of encoder 200 may also include pooling layers, fully connected layers, or other types of layers. Each neuron in a pooling layer may have a receptive field and may output an aggregate value based on the values in the receptive field of the neuron. For instance, a neuron in a pooling layer may output a maximum value of the values in the receptive field of the neuron, an average of the values in the receptive field of the neuron, or another type of aggregate value.

Decoder 202 may include a series of layers. The layers of decoder 202 may include an input layer, one or more hidden layers, and an output layer. The hidden layers of decoder 202 may include one or more deconvolutional layers or transposed convolutional layers. A neuron in a deconvolutional layer, sometimes called “transposed convolution” layer, may generate an output value based on values in a padded receptive field and weights of connections between the neuron and locations in the receptive field of the neuron. The padded receptive field may include values generated by neurons in a previous layer of decoder 202 and padding values.

In some examples, such as examples where premorbid reconstruction ML model 128 is implemented as a segmenter network, information generated by one or more non-final layers of encoder 200 may be input to one or more layers of decoder 202.

Input bone model 206 may be provided as input to encoder 200. Input bone model 206 may have one of a variety of formats. In some examples, input bone model 206 is a 3D matrix. In some examples where input bone model 206 is a 3D matrix, each location within the 3D matrix may indicate whether bone is present at the location. In some examples where input bone model 206 is a 3D matrix, each location within the 3D matrix may include an intensity value or luma value, which may indicate a density of bone or absence of bone at the location. In some examples, input bone model 206 may represent a point cloud. For instance, input bone model 206 may comprise an unstructured collection of point datasets. A point dataset may indicate coordinates of a point in the point cloud. The points in the point cloud may correspond to locations on a surface of a bone. Decoder 202 generates an output bone model 208 based on data in feature buffer 204. Output bone model 208 may be in the same or different format as input bone model 206. FIG. 9, which is described in greater detail below shows an example point cloud learning model that includes an encoder network that may act as encoder 200 and a decoder network that may act as decoder 202. FIG. 11, which is described in greater detail elsewhere in this disclosure, illustrates another example 3D convolutional selective autoencoder configured to generate point clouds representing premorbid bone models according to techniques of this disclosure.

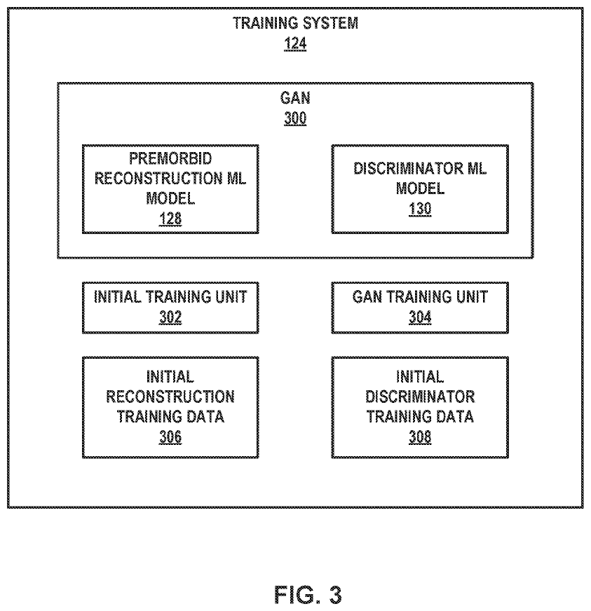

FIG. 3 is a block diagram illustrating example components of training system 124, in accordance with one or more techniques of this disclosure. In the example of FIG. 3, training system 124 includes a GAN 300 that includes premorbid reconstruction ML model 128 and discriminator ML model 130. Additionally, training system 124 may include an initial training unit 302 and a GAN training unit 304. In other examples, training system 124 may include more, fewer, or different components than shown in the example of FIG. 3.

Initial training unit 302 may perform initial training on premorbid reconstruction ML model 128. Initial training unit 302 may use initial reconstruction training data 306 to perform initial training on premorbid reconstruction ML model 128. Initial reconstruction training data 306 may include training datasets. Each of the training datasets of initial reconstruction training data 306 may include a premorbid bone model of a bone, such as a scapula, humerus, tibia, talus, femur, hip, radius, ulna, fibula, vertebra, or other bone. When performing the initial training on premorbid reconstruction ML model 128, initial training unit 302 may apply premorbid reconstruction ML model 128 to a premorbid bone model of a training dataset to generate an output bone model. Initial training unit 302 may then apply an error function to determine a loss value. The loss value may correspond to an amount of difference between the premorbid bone model of the training dataset and the output bone model. For instance, the loss value may be a total of distances between each point of the premorbid bone model and the closest point of the output bone model. In some examples, the loss value may be a dice loss. Initial training unit 302 may perform a backpropagation process to update parameters (e.g., weights of connections between artificial neurons of premorbid reconstruction ML model 128) based on the loss value. In some examples, the loss value used for backpropagation is an average of loss values so calculated for training examples in a batch of training examples, ½ multiplied by a sum of squares of loss values so calculated for multiple training datasets, or a mean squared error of loss values so calculated for multiple training datasets. Initial training unit 302 may perform this process for multiple batches of training examples. In this way, initial training unit 302 trains both encoder 200 and decoder 202 of premorbid reconstruction ML model 128 so that premorbid reconstruction ML model 128 reconstructs output bone models that are as close as possible to the premorbid bone models of the training datasets. The training performed by initial training unit 302 on premorbid reconstruction ML model 128 may be sufficient for training encoder 200 of premorbid reconstruction ML model 128 to determine appropriate values of feature buffer 204.

In some examples, if there is sufficient initial reconstruction training data 306 (e.g., a large enough number of premorbid bone models), it may be unnecessary to further train premorbid reconstruction ML model 128 using GAN 300. Rather, after training using premorbid bone models in initial reconstruction training data, premorbid reconstruction ML model 128 may be ready for use in production.

Discriminator ML model 130 may include a series of layers. The layers of discriminator ML model 130 may include an input layer, one or more hidden layers, and an output layer. The hidden layers of discriminator ML model 130 may include one or more convolutional layers. A neuron in a convolutional layer may generate an output value based on values in a padded receptive field and weights of connections between the neuron and locations in the receptive field of the neuron. The padded receptive field may include values generated by neurons in a previous layer of discriminator ML model 130 and padding values. In some examples, discriminator ML model 130 may include five 5×5×5 convolutional layers plus an activation layer. In other examples, discriminator ML model 130 may include five 3×3×3 convolutional layers plus an activation layer. Example activations functions may include a parametric rectified linear unit (PReLU) activation function, a rectified linear unit (ReLU) activation function, or other types of activation functions.

GAN training unit 304 may continue to train premorbid reconstruction ML model 128 and discriminator ML model 130 as part of GAN 300. For example, GAN training unit 304 may alternate between performing one or more training epochs to train premorbid reconstruction ML model 128 and one or more training epochs to train discriminator ML model 130. GAN training unit 304 may perform the plurality of training iterations during such a training epoch. During a training iteration, premorbid reconstruction ML model 128 may generate, based on input data for the training iteration, an output bone model for the training iteration. For example, GAN training unit 304 may inject randomized data into feature buffer 204 (FIG. 2) of premorbid reconstruction ML model 128. In some examples, the randomized data includes random noise.

GAN training unit 304 may provide the output bone model generated by premorbid reconstruction ML model 128 to discriminator ML model 130. Discriminator ML model 130 may generate, based on the output bone model for the training iteration, a discriminator output for the training iteration. The discriminator output for the training iteration may comprise a first value indicating a level of confidence that premorbid reconstruction ML model 128 generated the output bone model for the training iteration and a second value indicating a level of confidence that premorbid reconstruction ML model 128 did not generate the output bone model for the training iteration. In training iterations, GAN training unit 304 may provide the generated premorbid bone models and/or premorbid bone models not generated by premorbid reconstruction ML model 128 to discriminator ML model 130.

GAN training unit 304 may determine a loss value for the training iteration based on the discriminator output for the respective training iteration. GAN training unit 304 may update parameters of premorbid reconstruction ML model 128 and/or discriminator ML model 130 based on the loss value for the respective training iteration. GAN training unit 304 may determine the loss value for the training iteration in one of a variety of ways. For instance, in an example where the discriminator output includes a first value indicating a level of confidence that the discriminator input bone model (which may be the output bone model of premorbid reconstruction ML model 128 or a model of a real premorbid bone) for the training iteration was generated by premorbid reconstruction ML model 128 and a second value indicating a level of confidence that the discriminator input bone model for the training iteration was not generated by premorbid reconstruction ML model 128, GAN training unit 304 may calculate a cross-entropy loss value based on the first value, the second value, and a value indicating whether the output bone model actually represents a premorbid bone. If discriminator ML model 130 correctly determined the discriminator input bone model was generated by premorbid reconstruction ML model 128, GAN training unit 304 may use the cross-entry loss value to perform backpropagation on each layer of discriminator ML model 130 and each layer of decoder 202 of premorbid reconstruction ML model 128. In other words, the backpropagation may proceed as though the layers of discriminator ML model 130 were concatenated to the layers of decoder 202 of premorbid reconstruction ML model 128. On the other hand, if discriminator ML model 130 makes an incorrect determination (e.g., if discriminator ML model 130 determines that the discriminator input bone model was generated by premorbid reconstruction ML model 128 when the discriminator input bone model was not generated by premorbid reconstruction ML model 128 or if discriminator ML model 130 determines that the discriminator input bone model was not generated by premorbid reconstruction ML model 128 when the discriminator input bone model was generated by premorbid reconstruction ML model 128), GAN training unit 304 may use the cross-entropy loss value to perform backpropagation on each layer of discriminator ML model 130 without changing weights of premorbid reconstruction ML model 128.

In general, when performing the backpropagation process, a loss value may be calculated, e.g., as discussed above. For each weight of each neuron of each layer of neurons of a neural network, a change value for the weight may be calculated based on the loss value. The error value can be seen as an output of a function taking as a parameter an n-dimensional array containing the weights of the neural network. A change value for a weight represents a step descending a gradient of the error function along a dimension associated with the weight. Thus, the change value for the weight may be equal to a partial derivative of the weight with respect to the loss value. An updated value of the weight may be determined by subtracting the change value, multiplied by a learning rate, from the weight. In some examples, initial training unit 302 may add Gaussian error values to the change values for weights of neurons that generate values included in feature buffer 204. The Gaussian error values are values that have a Gaussian distribution centered on 0. In some examples, initial training unit 302 may add a regularizer value, such as mean squared error value, to the change values for the weights of the neurons. Addition of the Gaussian error values or other regularizer values may promote a more stable training process.

In some examples, discriminator ML model 130 outputs a single discriminator output that indicates a level of confidence that the discriminator input bone model is a “real” discriminator input (i.e., a discriminator input not generated by premorbid reconstruction ML model 128). Thus, the discriminator output may be closer to 1 if discriminator ML model 130 has greater confidence that the discriminator input is “real.” The discriminator output may be closer to 0 if discriminator ML model 130 is less confident that the discriminator input is “real.” In other words, the discriminator output may be closer to 0 if discriminator ML model 130 is more confident that the discriminator input is “fake” (i.e., that premorbid reconstruction ML model 128 generated the discriminator input bone model).

GAN training unit 304 may use a loss function based on binary cross-entropy to train GAN 300 (i.e., to train premorbid reconstruction ML model 128 and discriminator ML model 130). The general form of a binary cross-entropy loss function is represented below:

$$ℒ = - \sum y * ln ( \hat{y} ) ) + ( 1 - y ) * ln ( 1 - \hat{y} )$$

where [symbol] is a loss value, y is the ground truth (e.g., y is equal to 0 if the discriminator input bone model was generated by premorbid reconstruction ML model 130 and y is equal to 1 if premorbid reconstruction ML model 128 did not generate the discriminator input bone model), ÿ is the output of discriminator ML model 130, and the summation is over each possible value of y (i.e., 0 and 1). When the discriminator input is “real,” the output of discriminator model 130 (i.e., ŷ) is D(x), where D is a function representing operation of discriminator ML model 130 and x is the discriminator input bone model. When the discriminator input is “fake,” the output of discriminator model 130 (i.e., ŷ) is D(G(z)), where G is a function representing operation of premorbid reconstruction ML model 128 and z is input to decoder 202 of premorbid reconstruction ML model 128.

Thus, when the discriminator input is “fake,” the loss function may be written as:

$$ℒ = y * ln ( D ( G ( z ) ) ) + ( 1 - y ) * ln ( 1 - D ( G ( z ) ) )$$

Because discriminator ML model 130 should output 0 when the discriminator input is “fake,” the above equation may be simplified as:

$$ℒ = 0 * ln ( D ( G ( z ) ) ) + ( 1 - 0 ) * ln ( 1 - D ( G ( z ) ) ) = ln ( 1 - D ( G ( z ) ) )$$

On the other hand, when the discriminator input is “real,” the loss function may be written as:

$$ℒ = y * ln ( D ( x ) ) + ( 1 - y ) * ln ( 1 - D ( x ) )$$

Note that G is not in the equation above because premorbid reconstruction ML model 128 was not involved in the generation of the discriminator input. In the above equation, x is the discriminator input. Because discriminator ML model 130 should output I when the discriminator input is “real,” the above equation may be simplified as:

$$ℒ = 1 * ln ( D ( x ) ) + ( 1 - 1 ) * ln ( 1 - D ( x ) ) = ℒ = ln ( D ( x ) )$$

Thus, the loss function of GAN 300 (i.e., premorbid reconstruction ML model 128 and discriminator ML model 130) as a whole may be represented as:

$$ℒ = ln ( D ( x ) ) + ln ( 1 - D ( G ( z ) ) )$$

It may be more efficient to train GAN 300 using a backpropagation process that uses a loss value that is determined based on multiple inputs to GAN 300 (i.e., inputs to decoder 202 of premorbid reconstruction ML model 128 and real premorbid bone models to discriminator ML model 130) than a loss value that is determined based on a single input to GAN 300. Thus, during a training epoch, GAN 300 may provide multiple inputs to GAN 300 and determine multiple loss values. GAN 300 may then determine an expected value of the loss values. The expected value of the loss values may be a form of an average of the loss values. The expected value of the loss values may be the sum of the expected loss values for “real” discriminator inputs and the expected loss values for “fake” discriminator inputs. Thus, the loss value that GAN training unit 304 may use for the backpropagation process (i.e., the expected loss value) may be represented as:

$$E ( ℒ ) = E ( ln ( D ( x ) ) ) + E ( ln ( 1 - D ( G ( z ) ) ) )$$

GAN training unit 304 may train premorbid reconstruction ML model 128 and discriminator ML model 130 in alternating periods. Each of the periods may include one or more training epoch. When GAN training unit 304 is training discriminator ML model 130, GAN training unit 304 may provide multiple inputs to GAN 300 (e.g., inputs to decoder 202 of premorbid reconstruction ML model 128 and real premorbid bone models to discriminator ML model 130). When the input to GAN 300 is an input to decoder 202 of premorbid reconstruction ML model 128, GAN training unit 304 may perform forward propagation through premorbid reconstruction ML model 128 and discriminator ML model 130. When the input to GAN 300 is a real premorbid bone model, GAN training unit 304 performs forward propagation only through discriminator ML model 130. In either case, GAN training unit 304 may determine loss values for each input to GAN 300 and use these loss values to determine an expected loss value, e.g., as shown in the equation above. For instance, if there are m inputs to GAN 300, GAN training unit 300 may add together the loss values and divide the resulting sum by m. GAN training unit 304 may then use the expected loss value in a backpropagation process to update the weights of discriminator ML model 130. The backpropagation process used to update the weights of discriminator ML model 130 may use gradient ascent. The backpropagation process used to update the weights of discriminator ML model 130 may be represented by the following equation:

$$\frac{\partial }{\partial {θ}_{d}} \frac{1}{m} [ ln ( D ( x ) + ln ( 1 - D ( G ( z ) ) ) ]$$

where θ_{d} is a weight of discriminator ML model 130 and m is the number of inputs to GAN 300. GAN training unit 304 does not update the weights of premorbid reconstruction ML model 128 during a training period for discriminator ML model 130.

After completing a training period for discriminator ML model 130, GAN training unit 304 may initiate a training period for premorbid reconstruction ML model 128. When GAN training unit 304 is training premorbid reconstruction ML model 130, GAN training unit 304 may provide multiple inputs to decoder 202 of premorbid reconstruction ML model 130 and may perform forward propagation through decoder 202 of premorbid reconstruction ML model 128 and discriminator ML model 130. GAN training unit 304 may determine loss values for each input to decoder 202 and use these loss values to determine an expected loss value. GAN training unit 304 may then use the expected loss value in a backpropagation process to update weights of decoder 202 of premorbid reconstruction ML model 128. The backpropagation process used to update the weights of decoder 202 of premorbid reconstruction ML model 128 may use gradient descent, which may be represented by the following equation:

$$\frac{\partial }{\partial {θ}_{g}} \frac{1}{m} [ ln ( 1 - D ( G ( z ) ) ]$$

where Θ_{g} is a weight of premorbid reconstruction ML model 128 and m is the number of inputs to GAN 300. GAN training unit 304 does not update weights of encoder 200 of premorbid reconstruction ML model 128.

In some examples, GAN training unit 300 may provide premorbid bone models as input to encoder 200 of premorbid reconstruction ML model 128 during some training iterations as well as providing random input to decoder 202 of premorbid reconstruction ML model 128. In either case, GAN training unit 300 may provide the output of decoder 202 of premorbid reconstruction ML model 128 as input to discriminator ML model 130. In training iterations in which GAN training unit 300 provides premorbid bone models as input to encoder 200 of premorbid reconstruction ML model 128, the backpropagation process may continue through the layers of encoder 200.

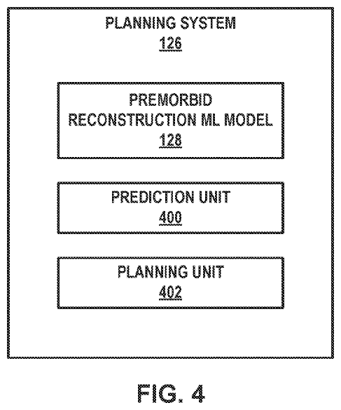

FIG. 4 is a block diagram illustrating example components of planning system 126, in accordance with one or more techniques of this disclosure. In the example of FIG. 4, planning system 126 include premorbid reconstruction ML model 128, a prediction unit 400, and a planning unit 402. Prediction unit 400 may obtain a morbid bone model of a patient, e.g., from one of patient datasets 118. Additionally, prediction unit 400 may apply premorbid reconstruction ML model 128 to the morbid bone model to generate a premorbid bone model. For example, prediction unit 400 may provide the morbid bone model as input to an input layer of encoder 200 (FIG. 2) of premorbid reconstruction ML model 128.

Planning unit 402 may use the premorbid bone model to assist a surgeon in planning an orthopedic surgery. For example, planning unit 402 may use the premorbid bone model and morbid bone model as input to a ML model that recommends an orthopedic prosthesis, bone graft, etc. In some examples, planning unit 402 may output the premorbid bone model for display to the surgeon.

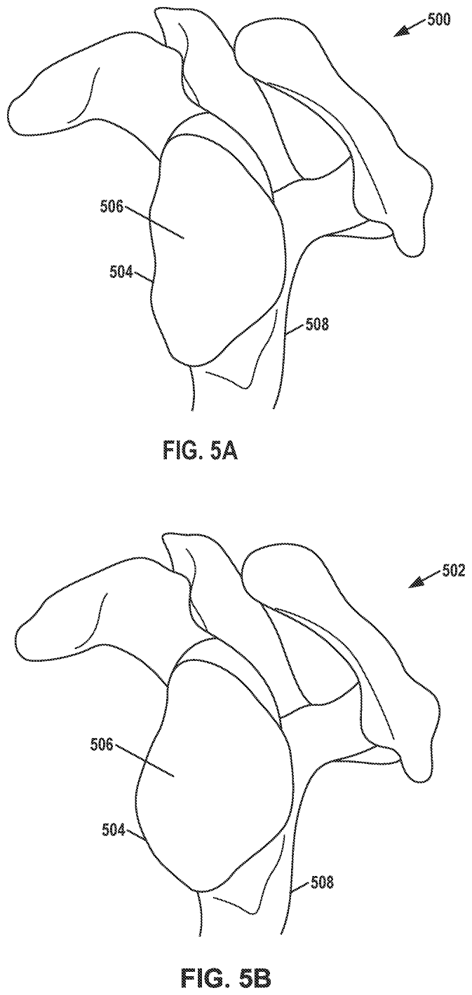

FIG. 5A is a conceptual diagram illustrating an example morbid bone model 500. FIG. 5B is a conceptual diagram illustrating an example premorbid bone model 502. Planning system 126 may apply premorbid reconstruction ML model 128 to morbid bone model 500 to generate premorbid bone model 502. An anterior boundary 504 of a glenoid fossa 506 of scapula 508 is deformed in morbid bone model 500. Deformation of anterior boundary 504 may be attributable to injury, arthritis, or another type of pathology. An estimated premorbid anterior boundary 510 of glenoid fossa 506 of scapula 508 is shown in a premorbid bone model 502.

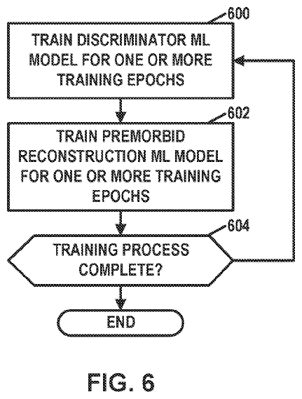

FIG. 6 is a flowchart illustrating an example operation of training system 124, in accordance with one or more techniques of this disclosure. The flowcharts of this disclosure are provided as examples. In other examples, operations may include more, fewer, or different actions, or actions may be performed in different orders.

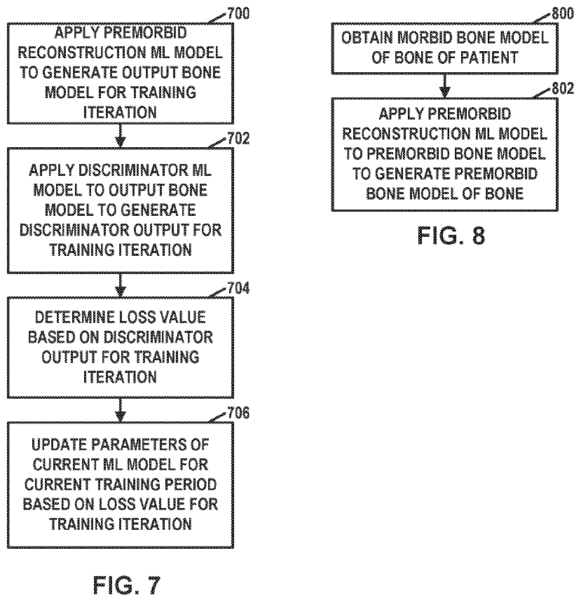

GAN training unit 304 may train premorbid reconstruction ML model 128 and discriminator ML model 130 in alternating periods. Thus, in the example of FIG. 6, GAN training unit 304 may train discriminator ML model 130 for one or more training epochs (600). GAN training unit 304 may then train premorbid reconstruction ML model 128 for one or more training epochs (602). A training epoch is a batch of training iterations. FIG. 7, which is discussed in greater detail below, illustrates an example operation performed by GAN training unit 304 during a training iteration.

After training discriminator ML model 130 for one or more training epochs and premorbid reconstruction ML model 128 for one or more training epochs, GAN training unit 304 may determine whether the training process is complete (604). If the training process is not complete (“NO” branch of 604), GAN training unit 304 may again train discriminator ML model 130 for one or more training epochs (600) and premorbid reconstruction ML model 128 for one or more training epochs (602). Otherwise, if the training process is complete (“YES” branch of 604), the training process may end. GAN training unit 304 may determine that the training process is complete in one of a variety of ways. For instance, GAN training unit 304 may determine that the training process is complete when discriminator output generated by discriminator ML model 130 has approximately 50% accuracy.

FIG. 7 is a flowchart illustrating an example operation performed by GAN training unit 304 during a training iteration, in accordance with one or more techniques of this disclosure. In the example of FIG. 7, GAN training unit 304 may apply premorbid reconstruction ML model 128 of GAN 300 to input data for the training iteration to generate an output bone model for the respective training iteration (700). Premorbid reconstruction ML model 128 may comprise an autoencoder or other type of ML model, such as a U-Net or V-Net ML model. In some examples, premorbid reconstruction ML model 128 has previously been trained to reconstruct premorbid bone models based on training premorbid bone models. The input data for the training iteration may include randomized data. For instance, the input data may include a series of random (or pseudorandom) numbers. Applying premorbid reconstruction ML model 128 to the input data for the training iteration may include injecting the input data into feature buffer 204 (FIG. 2) of premorbid reconstruction ML model 128. In this way, GAN training unit 304 may inject the input data into the decoder 202 of premorbid reconstruction ML model 128. Thus, in some examples, the input data for the training iteration is not processed through encoder 200 of premorbid reconstruction ML model 128. However, during application of premorbid reconstruction ML model 128 to the input data for the training iteration, decoder 202 of premorbid reconstruction ML model 128 processes the input data to generate an output bone model.

Furthermore, in the example of FIG. 7, GAN training unit 304 may apply discriminator ML model 130 of GAN 300 to the output bone model for the training iteration to generate a discriminator output for the training iteration (702). The discriminator output for the respective training iteration may comprise a level of confidence that the output bone model for the respective training iteration was generated by premorbid reconstruction ML model 128. In some examples, the level of confidence may be an estimated probability that the output bone model was generated by premorbid reconstruction ML model 128. In other examples, the level of confidence may be in a range other than [0, 1] and may or may not have a direct relationship with the probability that the output bone model was generated by premorbid reconstruction ML model 128. Applying discriminator ML model 130 to the output bone model for the training iteration may involve providing the output bone model to an input layer of discriminator ML model 130 and performing a feedforward pass through discriminator ML model 130 to generate the discriminator output for the training iteration.

GAN training unit 304 may determine a loss value for the training iteration based on the discriminator output for the training iteration (704). GAN training unit 304 may determine the loss value for the training iteration in accordance with any of the examples provided elsewhere in this disclosure.

Furthermore, GAN training unit 304 may update parameters of premorbid reconstruction ML model 128 or discriminator ML model 130 based on the loss value for the training iteration (706). For instance, if the training period is part of a period in which GAN training unit 304 is training premorbid reconstruction ML model 128, GAN training unit 304 may update the parameters of premorbid reconstruction ML model 128 based on the loss value for the training iteration. If the training period is part of a period in which GAN training unit 304 is training discriminator ML model 130, GAN training unit 304 may update the parameters of discriminator ML model 130 based on the loss value of training iteration. If GAN training unit 304 is training discriminator ML model 130, GAN training unit 304 may apply discriminator ML model 130 to bone models representing real premorbid bones and output bone models generated by premorbid reconstruction ML model 128. However, if GAN training unit 304 is training premorbid reconstruction ML model 128, GAN training unit 304 may apply discriminator ML model 130 only to output bone models generated by premorbid reconstruction ML model 128. GAN training unit 304 may use a backpropagation process to update the parameters (e.g., weights) of premorbid reconstruction ML model 128 or discriminator ML model 130 based on the loss value.

As previously mentioned, GAN training unit 304 may apply discriminator ML model 130 to bone models representing real premorbid bone. Thus, for each respective training iteration of an additional set of training iterations (e.g., a second plurality of training iterations) in which GAN training unit 304 applies discriminator ML model 130 to bone models representing real premorbid bones. GAN training unit 304 may apply discriminator ML model 130 to a real premorbid bone model for a respective training iteration of the additional set of training iterations to generate a discriminator output for the respective training iteration of the additional set of training iterations. The discriminator output for the respective training iteration of the additional set of training iterations may comprise a level of confidence that the output bone model for the respective training iteration of the additional set of training iterations was generated by the premorbid reconstruction ML model. GAN training unit 304 may determine a loss value for the respective training iteration of the additional set of training iterations based on the discriminator output for the respective training iteration of the additional set of training iterations. GAN training unit 304 may update parameters of discriminator ML model 130 based on the loss value for the respective training iteration of the additional set of training iterations.

FIG. 8 is a flowchart illustrating an example operation for generating a premorbid bone model in accordance with one or more techniques of this disclosure. In the example of FIG. 8, planning system 126 may obtain a morbid bone model of a bone of a patient (800). In some examples, planning system 126 obtains the morbid bone model from an imaging system, such as imaging system 116.

Planning system 126 may apply premorbid reconstruction ML model 128 to the morbid bone model to generate a premorbid bone model of the bone (802). Premorbid reconstruction ML model 128 has been trained in a GAN to generate premorbid bone models. For example, planning system 126 may provide the morbid bone model as input to encoder 200 of premorbid reconstruction ML model 128. Feature buffer 204 may store the output of encoder 200. Decoder 202 of premorbid reconstruction ML model 128 may use the data in feature buffer 204 to generate the premorbid bone model. In other words, planning system 126 may apply encoder 200 of premorbid reconstruction ML model 128 to the morbid bone model for the bone of the patient to generate a global feature vector and may apply the decoder of premorbid reconstruction ML model 128 to the global feature vector to generate the premorbid bone model for the bone of the patient. In some examples, the morbid bone model and the premorbid bone model comprise point clouds.

In some examples, premorbid reconstruction ML model 128 may associate some or all points of the premorbid bone model with point labels. For each point of the point cloud representing the premorbid bone model, the point may have a point label indicating whether the point is an unaffected part of the premorbid bone model or an affected part of the premorbid bone. Unaffected parts of the premorbid bone model are parts of the premorbid bone model representing parts of that bone that were unaffected by the morbidity affecting the bone, and therefore should be the same in a morbid bone model and the premorbid bone model. The affected parts of the premorbid bone model area parts of the premorbid bone model representing parts of the bone that were affected by the morbidity, and therefore are altered in the premorbid bone model relative to the morbid bone model.

Regardless of the quality of the premorbid bone model generated by premorbid reconstruction ML model 128, the unaffected parts of the premorbid bone model may have lower fidelity to corresponding parts of the morbid bone model because the morbid bone model may be generated directly from medical images of the actual bone. Therefore, after premorbid reconstruction ML model 128 generates the premorbid ML model, computing system 102 (e.g., planning system 126 of computing system 102) may modify the premorbid ML model at least in part by replacing unaffected parts of the premorbid bone model with corresponding parts of the morbid bone model. The resulting modified premorbid bone model may therefore have higher fidelity to the actual bone than the original premorbid bone model generated by premorbid reconstruction ML model 128. In some examples, as part of replacing the unaffected parts of the premorbid bone model with the corresponding parts of the morbid bone model, computing system 102 may align the premorbid bone model and the morbid bone model. Then, for each point of the premorbid bone model having a point label indicating that the point is an unaffected part of the premorbid bone model, computing system 102 may determine the closest point of the morbid bone model. Computing system 102 may then replace the point of the premorbid bone model with the determined point of the morbid bone model. In some examples, GAN training unit 304 may use the modified premorbid bone model as input to discriminator ML model 130.

The training of premorbid reconstruction ML model 128 may include training premorbid reconstruction ML model 128 to generate the point labels. Thus, in some examples, training system 124 may initially train premorbid reconstruction ML model 128 using initial reconstruction training data 306. Training datasets in initial reconstruction training data 306 may include premorbid bone models in which points have point labels indicating the bone corresponding to the points is affected or unaffected. During training, initial training unit 302 may provide the positions of points of a premorbid bone model to premorbid reconstruction ML model 128 as input without providing the point labels as input to premorbid reconstruction ML model 128. In some examples, initial training unit 302 may determine a loss value based on (e.g., as a sum of) (i) a total of distances between points of the generated premorbid bone model and closest points of the input premorbid bone model and (ii) a total of differences between point labels of points of the generated premorbid bone model and point labels of closest points of the input premorbid bone model. In some examples, initial training unit 302 may determine a loss value based on (e.g., as a sum of) (i) a total of distances between points of the generated premorbid bone model with point labels indicating that the points are unaffected by the pathology and closest points of the input premorbid bone model and (ii) a total of differences between point labels of points of the generated premorbid bone model and point labels of closest points of the input premorbid bone model. Initial training unit 302 may use backpropagation to update parameters (e.g., weights) of premorbid reconstruction ML model 128 based on the loss value. In some examples, the loss value used for backpropagation is an average of loss values so calculated for multiple training datasets, ½ multiplied by a sum of squares of loss values so calculated for multiple training datasets, or a mean squared error of loss values so calculated for multiple training datasets.

FIG. 9 is a conceptual diagram illustrating an example point cloud learning model 900 in accordance with one or more techniques of this disclosure. Point cloud learning model 900 may receive an input point cloud. The input point cloud is a collection of points. The points in the collection of points are not necessarily arranged in any specific order. Thus, the input point cloud may have an unstructured representation. The input point cloud may be a premorbid bone model or a morbid bone model.

In the example of FIG. 9, point cloud learning model 900 includes an encoder network 901 and a decoder network 902. Encoder network 901 receives an array 903 of n points. The points in array 903 may be the input point cloud of point cloud learning model 900. Each of the points in array 903 has a dimensionality of 3. For instance, in a Cartesian coordinate system, each of the points may have an x coordinate, a y coordinate, and a z coordinate.

Encoder network 901 may apply an input transform 904 to the points in array 903 to generate an array 905. Encoder network 901 may then use a first shared multi-layer perceptron (MLP) 906 to map each of the n points in array 905 from three dimensions to a larger number of dimensions a (e.g., a=64 in the example of FIG. 9), thereby generating an array 907 of n×a (e.g., n×64 values). For ease of explanation, the following description of FIG. 9 assumes that a is equal to 64 but in other examples other values of a may be used. Encoder network 901 may then apply a feature transform 908 to the values in array 907 to generate an array 909 of n×64 values. For each of the n points in array 909, encoder network 901 uses a second shared MLP 910 to map the n points from a dimension to b dimensions (e.g., b=1024 in the example of FIG. 9), thereby generating an array 911 of n×b (e.g., n×1024 values). For ease of explanation, the following description of FIG. 9 assumes that b is equal to 1024 but in other examples other values of b may be used. Encoder network 901 applies a max pooling layer 912 to generate a global feature vector 913. In the example of FIG. 9, each of points n in global feature vector 913 has 1024 dimensions.

Thus, as part of applying an encoder (e.g., encoder network 901) of premorbid reconstruction ML model 128, computing system 102 may apply an input transform (e.g., input transform 904) to a first array (e.g., array 903) that comprises the point cloud to generate a second array (e.g., array 905), wherein the input transform is implemented using a first T-Net model (e.g., T-Net Model 926), apply a first MLP (e.g., MLP 906) to the second array to generate a third array (e.g., array 907), apply a feature transform (e.g., feature transform 908) to the third array to generate a fourth array (e.g., array 909), wherein the input transform is implemented using a second T-Net model (e.g., T-Net model 930), apply a second MLP (e.g., MPL 910) to the fourth array to generate a fifth array (e.g., array 911); and apply a max pooling layer (e.g., max pooling layer 912) to the fifth array to generate the global feature vector (e.g., global feature vector 913)

A fully-connected network 914 may map global feature vector 913 to k output classification scores. The value k is an integer indicating a number of classes. Each of the output classification scores corresponds to a different class. An output classification score corresponding to a class may indicate a level of confidence that the input point cloud as a whole corresponds to the class. Fully-connected network 914 includes a neural network having two or more layers of neurons in which each neuron in a layer is connected to each neuron in a subsequent layer. In the example of FIG. 9, fully-connected network 914 includes an input layer having 512 neurons, a middle layer having 256 neurons, and an output layer having k neurons. In some examples, fully-connected network 914 may be omitted from encoder network 901.

Input 916 to decoder network 902 may be formed by concatenating the n 64-dimensional points of array 909 with global feature vector 913. In other words, for each point of the n points in array 909, the corresponding 64 dimensions of the point are concatenated with the 1024 features in global feature vector 713.

Decoder network 902 may sample N points in a unit square in 2-dimensions. Thus, decoder network 902 may randomly determine N points having x-coordinates in a range of [0,1] and y-coordinates in the range of [0,1]. For each respective point of the N points, decoder network 902 may obtain a respective input vector by concatenating the respective point with global feature vector 913. Thus, in examples where array 909 is not concatenated with global feature vector 913, each of the input vectors may have 1026 features. For each respective input vector, decoder network 902 may apply each of K MLPs 918 (where K is an integer greater than or equal to 1) to the respective input vector. Each of MLPs 918 may correspond to a different patch (e.g., area) of the output point cloud. When decoder network 902 applies the MLP to an input vector, the MLP may generate a 3-dimensional point in the patch (e.g., area) corresponding to the MLP. Thus, each of the MLPs 918 may reduce the number of features from 1026 to 3. The 3 features may correspond to the 3 coordinates of a point of the output point cloud. For instance, for each sampled point n in N, the MLPs 918 may reduce the features from 1026 to 512 to 256 to 128 to 64 to 3. Thus, decoder network 902 may generate a K×N×3 vector containing an output point cloud 320. In some examples, K=16 and N=512, resulting in second point cloud with 8192 3D points. In other examples, other values of K and N may be used. In some examples, as part of training the MLPs of decoder network 902, decoder network 902 may calculate a chamfer loss of an output point cloud relative to a ground-truth point cloud. Decoder network 902 may use the chamfer loss in a backpropagation process to adjust parameters of the MLPs. In this way, planning system 126 may apply the decoder (e.g., decoder network 902) to generate the premorbid bone model based on the global feature vector.

In some examples, MLPs 918 may include a series of four fully-connected layers of neurons. For each of MLPs 918, decoder network 902 may pass an input vector of 1026 features to an input layer of the MLP. The fully-connected layers may reduce to number of features from 1026 to 512 to 256 to 3.

Input transform 904 and feature transform 908 in encoder network 901 may provide transformation invariance. In other words, point cloud learning model 900 may be able to generate output point clouds (e.g., output bone models) in the same way, regardless of how the input point cloud (e.g., input bone model) is rotated, scaled, or translated. The fact that point cloud learning model 900 provides transform invariance may be advantageous because it may reduce the susceptibility of premorbid reconstruction ML model 128 to errors based on positioning/scaling in morbid bone models. As shown in the example of FIG. 9, input transform 904 may be implemented using a T-Net model 926 and a matrix multiplication operation 928. T-Net model 926 generates a 3×3 transform matrix based on array 903. Matrix multiplication operation 928 multiplies array 903 by the 3×3 transform matrix. Similarly, feature transform 908 may be implemented using a T-Net model 930 and a matrix multiplication operation 932. T-Net model 930 may generate a 64×64 transform matrix based on array 907. Matrix multiplication operation 928 multiplies array 907 by the 64×64 transform matrix.

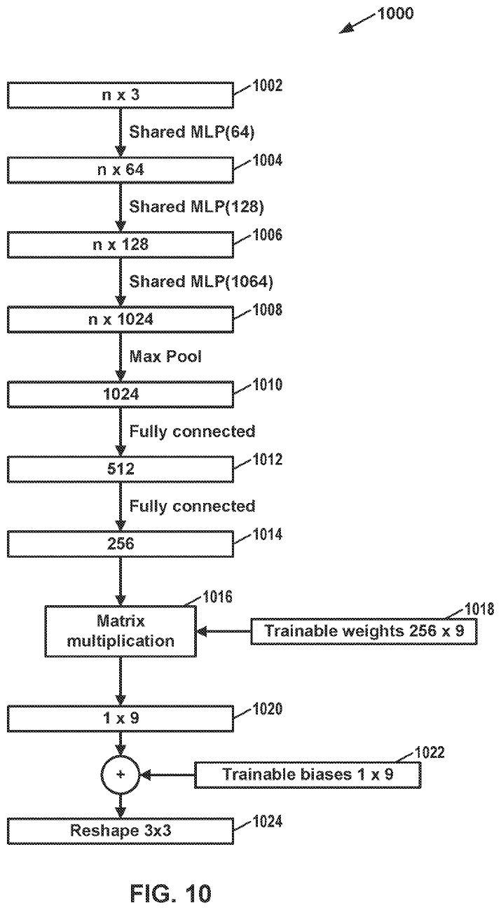

FIG. 10 is a block diagram illustrating an example architecture of a T-Net model 1000 in accordance with one or more techniques of this disclosure. T-Net model 1000 may implement T-Net model 926 used in the input transform 904. In the example of FIG. 10, T-Net model 1000 receives an array 1002 as input. Array 1002 includes n points. Each of the points has a dimensionality of 3. A first shared MLP maps each of the n points in array 1002 from 3 dimensions to 64 dimensions, thereby generating an array 1004. A second shared MLP maps each of the n points in array 1004 from 64 dimensions to 128 dimensions, thereby generating an array 1006. A third shared MLP maps each of the n points in array 1006 from 128 dimensions to 1024 dimensions, thereby generating an array 1008. T-Net model 1000 then applies a max pooling operation to array 1008, resulting in an array 810 of 1024 values. A first fully-connected neural network maps array 1010 to an array 812 of 512 values. A second fully-connected neural network maps array 1012 to an array 1014 of 256 values. T-Net model 1000 applies a matrix multiplication operation 1016 to a matrix of trainable weights 1018. The matrix of trainable weights 1018 has dimensions of 256×9. Thus, multiplying array 1014 by the matrix of trainable weights 1018 results in an array 820 of size 1×9. T-Net model 1000 may then add trainable biases 1022 to the values in array 1020. A reshaping operation 1024 may remap the values resulting from adding trainable biases 1022 into a 3×3 transform matrix. In other examples, the sizes of the matrixes and arrays may be different.

T-Net model 930 (FIG. 9) may be implemented in a similar way as T-Net model 1000 in order to perform feature transform 908. However, in this example, the matrix of trainable weights 1018 is 256×4096 and the trainable biases 1022 has size 1×4096 bias values instead of 9. Thus, the T-Net model for performing feature transform 908 may generate a transform matrix of size 64×64. In other examples, the sizes of the matrixes and arrays may be different.

FIG. 11 is a block diagram illustrating another example 3D convolutional selective autoencoder (3D-CSAE) 1100 configured to generate 3D images representing premorbid bone models according to techniques of this disclosure. In the example of FIG. 11, 3D-CSAE 1100 includes an encoder 1102 and a decoder 1104. Encoder 1102 receives an input image 1106 as input. Input image 1106 may be a 3D image of a morbid bone. Decoder 1104 may output an output image 1108. Output image 1108 may be a 3D image of a premorbid bone. Encoder 1102 includes layers 1110A-1110E (collectively, “encoder layers 1110”). Decoder 1104 includes layers 1112A-1112F (collectively, “decoder layers 1112”).

Encoder layers 1110A, 111B, and 1110D are convolution layers. Batch normalization (BN) is applied after each of encoder layers 1110A, 1110B, and 1110D. Encoder layers 1110C and 1110E are max pooling layers. In some examples, encoder layer 1110A is a 3×3×3 convolutional layer with 128 kernels, encoder layer 1110B is a 3×3×3 convolutional layer with 64 kernels, and encoder layer 110D is a 3×3×3 convolutional layer with 16 kernels. Encoder layers 1110C and 1110E may be 2×2×2 max pooling layers. In some examples, encoder layers 1110C and 1110E use dropout. Applying dropout after max pooling in encoder layers 1110C, 1110E may reduce over-fitting. Output of encoder layer 1110E may be a relatively low dimensional representation of input image 1106 that acts as input to decoder 1104.

In some examples, decoder layers 1112A, 1112C, 1112D, 1112F are 3×3×3 convolutional layers with 16, 64, 128, and 1 kernels, respectively. Batch normalization (BN) is applied after each of decoder layers 1112A, 1112C, 1112D, and 1112F. Decoder layers 1112B and 1112E may be 2×2×2 layers. The convolutional layers of 3D-CSAE 1110 may use ReLU activation functions. The kernels of the convolutional layers of 3D-CSAE 1100 may be initialized with random parameter values. Mean squared error (MSE) may be used as a loss function during training of 3D-CSAE 1110.

While the techniques been disclosed with respect to a limited number of examples, those skilled in the art, having the benefit of this disclosure, will appreciate numerous modifications and variations there from. For instance, it is contemplated that any reasonable combination of the described examples may be performed. It is intended that the appended claims cover such modifications and variations as fall within the true spirit and scope of the invention.

It is to be recognized that depending on the example, certain acts or events of any of the techniques described herein can be performed in a different sequence, may be added, merged, or left out altogether (e.g., not all described acts or events are necessary for the practice of the techniques). Moreover, in certain examples, acts or events may be performed concurrently, e.g., through multi-threaded processing, interrupt processing, or multiple processors, rather than sequentially.

In one or more examples, the functions described may be implemented in hardware, software, firmware, or any combination thereof. If implemented in software, the functions may be stored on or transmitted over as one or more instructions or code on a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transitory media, but are instead directed to non-transitory, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Operations described in this disclosure may be performed by one or more processors, which may be implemented as fixed-function processing circuits, programmable circuits, or combinations thereof, such as one or more digital signal processors (DSPs), general purpose microprocessors, application specific integrated circuits (ASICs), field programmable gate arrays (FPGAs), or other equivalent integrated or discrete logic circuitry. Fixed-function circuits refer to circuits that provide particular functionality and are preset on the operations that can be performed. Programmable circuits refer to circuits that can programmed to perform various tasks and provide flexible functionality in the operations that can be performed. For instance, programmable circuits may execute instructions specified by software or firmware that cause the programmable circuits to operate in the manner defined by instructions of the software or firmware. Fixed-function circuits may execute software instructions (e.g., to receive parameters or output parameters), but the types of operations that the fixed-function circuits perform are generally immutable. Accordingly, the terms “processor” and “processing circuitry,” as used herein may refer to any of the foregoing structures or any other structure suitable for implementation of the techniques described herein.

Various examples have been described. These and other examples are within the scope of the following claims.

1. A method comprising:
for each respective training iteration of a plurality of training iterations:
applying a first machine learning (ML) model of a generative adversarial network (GAN) to input data for the respective training iteration to generate an output bone model for the respective training iteration;
applying a second ML model of the GAN to the output bone model for the respective training iteration to generate a discriminator output for the respective training iteration, wherein the discriminator output for the respective training iteration comprises a level of confidence that the first ML model generated the output bone model for the respective training iteration;
determining a loss value for the respective training iteration based on the discriminator output for the respective training iteration; and
updating parameters of the first ML model or the second ML model based on the loss value for the respective training iteration;
obtaining a morbid bone model for a bone of a patient;
applying the first ML model to the morbid bone model to generate a premorbid bone model of the bone of the patient, wherein the morbid bone model is a first point cloud, the premorbid bone model is a second point cloud, and for each point of the second point cloud, the point has a point label indicating whether the point is associated with affected bone or unaffected bone; and
modifying the second point cloud to replace points associated with unaffected bone with corresponding points of the first point cloud.

2. (canceled)

3. The method of claim 1, further comprising prior to performing the plurality of training iterations, training the first ML model to reconstruct premorbid bone models based on training premorbid bone models.

4. The method of claim 3, wherein the training premorbid bone models comprise point clouds.

5. (canceled)

6. The method of claim 1, wherein the plurality of training iterations is a first plurality of training iterations and the method further comprises, for each respective training iteration of a second plurality of training iterations:
applying the second ML model to a real premorbid bone model for a respective training iteration of the second plurality of training iterations to generate a discriminator output for the respective training iteration of the second plurality of training iterations, wherein the discriminator output for the respective training iteration of the second plurality of training iterations comprises a level of confidence that the first ML model generated the real premorbid bone model for the respective training iteration of the second plurality of training iterations;
determining a loss value for the respective training iteration of the second plurality of training iterations based on the discriminator output for the respective training iteration of the second plurality of training iterations; and
updating parameters of the second ML model based on the loss value for the respective training iteration of the second plurality of training iterations.

7. The method of claim 1, wherein the first ML model comprises an encoder and a decoder and the method further comprises:
generating the input data; and
injecting the input data into the decoder.

8. The method of claim 7, wherein the method further comprises:
applying the encoder of the first ML model to the morbid bone model to generate a global feature vector; and
applying the decoder of the first ML model to the global feature vector to generate the premorbid bone model.

9. The method of claim 8, wherein:
applying the encoder of the first ML model to the morbid bone model comprises:
applying an input transform to a first array that comprises the first point cloud to generate a second array, wherein the input transform is implemented using a first T-Net model;
applying a first multi-layer perceptron (MLP) to the second array to generate a third array;
applying a feature transform to the third array to generate a fourth array, wherein the input transform is implemented using a second T-Net model;
applying a second MLP to the fourth array to generate a fifth array; and
applying a max pooling layer to the fifth array to generate the global feature vector.

10. The method of claim 1, further comprising:
applying a third ML model to generate synthetic morbid bone models; and
training the first ML model based on the synthetic morbid bone models.

11. A method for generating a premorbid bone model of a bone of a patient, the method comprising:
obtaining a morbid bone model of the bone of the patient;
applying a generator machine learning (ML) model to the morbid bone model to generate the premorbid bone model, wherein the morbid bone model is a first point cloud, the premorbid bone model is a second point cloud, for each point of the second point cloud, the point has a point label indicating whether the point is associated with affected bone or unaffected bone, and the generator ML model has been trained in a generative adversarial network (GAN) to generate output point clouds representing premorbid bone models; and
modifying the second point cloud to replace points associated with unaffected bone with corresponding points of the first point cloud.

12. (canceled)

13. The method of claim 11, wherein:
the generator ML model includes an encoder and a decoder,
applying the generator ML model to the morbid bone model to generate the premorbid bone model of the bone of the patient comprises:
applying an input transform to a first array that comprises the first point cloud to generate a second array, wherein the input transform is implemented using a first T-Net model;
applying a first multi-layer perceptron (MLP) to the second array to generate a third array;
applying a feature transform to the third array to generate a fourth array, wherein the input transform is implemented using a second T-Net model;
applying a second MLP to the fourth array to generate a fifth array; and
applying a max pooling layer to the fifth array to generate a global feature vector; and
applying the decoder to generate the second point cloud based on the global feature vector.

14. (canceled)

15. A computing system comprising:
a storage system configured to store a first machine learning (ML) model of a generative adversarial network (GAN) and a second ML model of the GAN; and
processing circuitry configured to, for each respective training iteration of a plurality of training iterations:
apply the first ML model to input data for the respective training iteration to generate an output bone model for the respective training iteration;
apply the second ML model to the output bone model for the respective training iteration to generate a discriminator output for the respective training iteration, wherein the discriminator output for the respective training iteration comprises a level of confidence that the first ML model generated the output bone model for the respective training iteration;
determine loss value for the respective training iteration based on the discriminator output for the respective training iteration; and
update parameters of the first ML model or the second ML model based on the loss value for the respective training iteration;
obtain a morbid bone model for a bone of a patient;
apply the first ML model to the morbid bone model to generate a premorbid bone model of the bone of the patient, wherein the morbid bone model is a first point cloud, the premorbid bone model is a second point cloud, and for each point of the second point cloud, the point has a point label indicating whether the point is associated with affected bone or unaffected bone; and
modify the second point cloud to replace points associated with unaffected bone with corresponding points of the first point cloud.

16. (canceled)

17. The computing system of claim 15, wherein the processing circuitry is configured to, prior to performing the plurality of training iterations, train the first ML model to reconstruct premorbid bone models based on the training premorbid bone models.

18. The computing system of claim 17, wherein the training premorbid bone models comprise point clouds.

19. (canceled)

20. The computing system of claim 15, wherein the plurality of training iterations is a first plurality of training iterations and the processing circuitry is further configured to, for each respective training iteration of a second plurality of training iterations:
generate, using the second ML model, based on a real premorbid bone model for a respective training iteration of the second plurality of training iterations, a discriminator output for the respective training iteration of the second plurality of training iterations, wherein the discriminator output for the respective training iteration of the second plurality of training iterations comprises a level of confidence that the first ML model generated the output bone model for the respective training iteration of the second plurality of training iterations;
determine a loss value for the respective training iteration of the second plurality of training iterations based on the discriminator output for the respective training iteration of the second plurality of training iterations; and
update parameters of the second ML model based on the loss value for the respective training iteration of the second plurality of training iterations.

21. The computing system of claim 15, wherein the first ML model comprises an encoder and a decoder and the processing circuitry is further configured to:
generate the input data; and
inject the input data into the decoder.

22. The computing system of claim 21, wherein the processing circuitry is further configured to:
apply the encoder of the first ML model to the morbid bone model to generate a global feature vector; and
apply the decoder of the first ML model to the global feature vector to generate the premorbid bone model.

23. The computing system of claim 22, wherein:
the processing circuitry is configured to, as part of applying the encoder of the first ML model to the morbid bone model:
apply an input transform to a first array that comprises the first point cloud to generate a second array, wherein the input transform is implemented using a first T-Net model;
apply a first MLP to the second array to generate a third array;
apply a feature transform to the third array to generate a fourth array, wherein the input transform is implemented using a second T-Net model;
apply a second MLP to the fourth array to generate a fifth array; and
apply a max pooling layer to the fifth array to generate the global feature vector.

24. The computing system of claim 15, wherein the processing circuitry is configured to:
apply a third ML model to generate synthetic morbid bone models; and
train the first ML model based on the synthetic morbid bone models.

25-30. (canceled)
